(19) United States
(12) Patent Application Publication
(10) Pub. No.: US 2026/0255592 A1
(43) Pub. Date: Aug. 27, 2026

(54) MEMORY DEVICES ACROSS MULTIPLE SEMICONDUCTOR DIES AND METHODS FOR MANUFACTURING THE SAME

(71) Applicant: Taiwan Semiconductor Manufacturing Company, Ltd., Hsinchu (TW)

(72) Inventors: Meng-Sheng Chang, Hsinchu City (TW); Yih Wang, Hsinchu City (TW)

(73) Assignee: Taiwan Semiconductor Manufacturing Company, Ltd., Hsinchu (TW)

(21) Appl. No.: 19/265,353

(22) Filed: Jul. 10, 2025

Related U.S. Application Data
(60) Provisional application No. 63/764,024, filed on Feb. 27, 2025.

(51) Int. Cl. H10B 20/25; H01L 23/00; H01L 25/00; H01L 25/065; H10B 80/00

(52) U.S. Cl. CPC H10B 20/25; H10B 80/00; H10W 90/00; H10W 90/722

(57) ABSTRACT

A semiconductor device includes a first semiconductor die including a plurality of first transistors, wherein the plurality of first transistors each have a first gate feature; and a second semiconductor die coupled to the first semiconductor die through a plurality of bump structures, and including a plurality of second transistors, wherein the plurality of second transistors each have a second gate feature smaller than the first gate feature. At least a subset of the plurality of first transistors, operatively serve as one or more power switches, are configured to receive a first supply voltage and electrically couple the first supply voltage to a subset of the plurality of second transistors for a period of time.

### CROSS-REFERENCE TO RELATED APPLICATION

This application claims priority to and the benefit of U.S. Provisional Application No. 63/764,024, filed Feb. 27, 2025, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit, in accordance with some embodiments.

FIG. 2 illustrates an example schematic diagram of a memory cell included in the memory circuit of FIG. 1, in accordance with some embodiments.

FIG. 3 illustrates an example block diagram of the memory circuit of FIG. 1, in accordance with some embodiments.

FIG. 4 illustrates another example block diagram of the memory circuit of FIG. 1, in accordance with some embodiments.

FIG. 5 illustrates an example schematic diagram of the memory circuit implemented based on the block diagram of FIG. 3 and formed across multiple semiconductor dies, in accordance with some embodiments.

FIG. 6 illustrates an example schematic diagram of bump structures formed on the semiconductor dies shown in FIG. 5, in accordance with some embodiments.

FIG. 7 illustrates an example schematic diagram of the memory circuit implemented based on the block diagram of FIG. 4 and formed across multiple semiconductor dies, in accordance with some embodiments.

FIG. 8 illustrates an example schematic diagram of bump structures formed on the semiconductor dies shown in FIG. 7, in accordance with some embodiments.

FIG. 9 illustrates an example circuit diagram of a power switch of the memory circuit of FIG. 1, in accordance with some embodiments.

FIG. 10 illustrates another example schematic diagram of the memory circuit implemented based on the block diagram of FIG. 3 and formed across multiple semiconductor dies, in accordance with some embodiments.

FIG. 11 illustrates an example flowchart of a method for fabricating a memory circuit across multiple dies, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

With the ever increasing pace to advance to the next generation nodes, input/output (I/O) needs of a system typically deal with transferring signals between integrated circuit dies and component connections having large capacitances, such as those associated with printed circuit board traces, cables etc., that require larger driving power and voltage than the signaling occurring within the integrated circuit die. I/O devices interface the faster, smaller signals of a main die to these other, higher capacitance components, and typically transfer the signals at higher voltages. As a non-limiting example, a memory circuit (e.g., an efuse memory circuit or otherwise one-time programmable (OTP) memory circuit) typically relies on an I/O circuit to provide a high voltage for operation of the memory circuit (e.g., programing, erasing, etc.).

A voltage provision circuit (sometimes referred to as a power switch) is one of various such I/O circuits, operatively coupled to a memory circuit, that can provide a desired operation voltage (e.g., a relatively high operation voltage). Such a power switch typically includes a level shifter, which, in general, can shift the level of a supply voltage from one voltage domain to another voltage domain. For example, when a memory cell of the memory circuit is configured in a program mode, the power switch generally provides the memory cell with an operation voltage shifted from a first supply voltage to a second supply voltage, alternatively stated, from a lower voltage domain to a higher voltage domain. Generally, the power switch continuously receives the higher supply voltage, and provides the higher supply voltage to the memory cell as needed.

However, as the memory cell keeps advancing to the next generation of technology nodes, manufacturing such a power switch, that is configured to continuously receive (or “see”) the high supply voltage, may become an issue. For example, in the advanced technology node, a semiconductor die or wafer tends to have its all transistors formed with a single (e.g., short) gate length. Stated another way, all the transistors on a single die may be configured with a small dimension, which causes the transistors to tolerate with a relatively lower operation voltage. In this regard, some approaches have been proposed such as, stacking multiple these transistors with the small dimension. However, design of the whole circuit tends to become complex. For example, with all the transistors formed with the stacking structure (coupling multiple transistors to each other in series), one or more other voltage provision circuits that can provide a fraction of the high supply voltage generally need to be included in the memory circuit. Further, a total area occupied by such stacking transistors (and additional circuits) tends to become disadvantageously large. Thus, the existing memory circuit has not been entirely satisfactory in certain aspects.

The present disclosure provides various embodiments of a memory circuit fabricated across multiple semiconductor dies bonded to one another, each of which may have its transistors formed with one or more respective gate lengths. In some embodiments, a first one of the multiple semiconductor dies may have its transistors (first transistors) formed in a FinFET structure or a planar transistor structure, and a second one of the multiple semiconductor dies may have its transistors (second transistors) formed in a Gate-All-Around (GAA) transistor structure or any other advanced transistor structures (e.g., the complementary field-effect-transistor structure). Further, the first transistors can have one or more first gate features, while the second transistors may have a single second gate length, where the second gate feature is substantially shorter than any of the one or more first gate lengths. Herein, the term “gate feature” can refer to the physical dimension of one or more gate components of a gate structure. For example, such physical dimensions can include the gate length of a (e.g., metal) gate structure, a physical thickness of a gate dielectric layer, and an effective thickness of a gate dielectric layer. Typically, the gate length of a transistor refers to a length of the transistor's gate structure extending from the transistor's source structure to the transistor's drain structure.

In one aspect of the present disclosure, the memory circuit can include a power switch formed with the first transistors (or formed on the first semiconductor die), and all other circuits, including memory cells, formed with the second transistors (or formed on the second semiconductor die). With this configuration, the memory circuit can operate with a substantially high operation (supply) voltage, without forming the memory cells in the stacking structure. In another aspect of the present disclosure, the memory circuit can include a power switch and memory cells formed with the first transistors (or formed on the first semiconductor die), and all other circuits formed with the second transistors (or formed on the second semiconductor die). With this configuration, a density of the memory cells can significantly increase as the memory cells can be formed without the stacking structure.

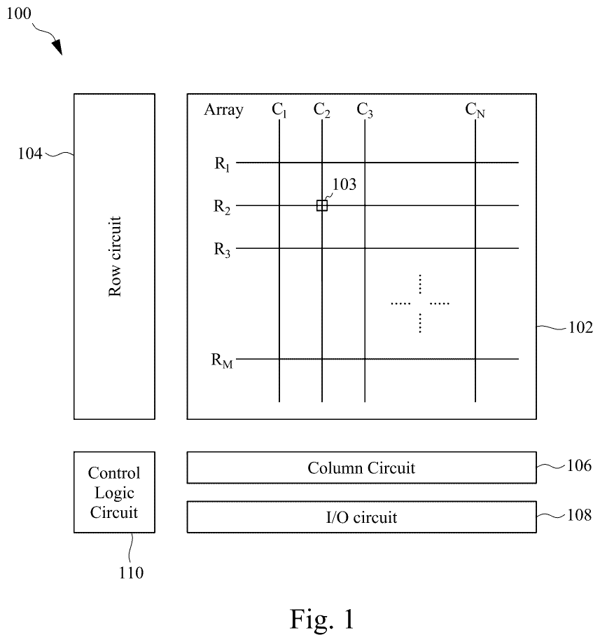

FIG. 1 illustrates a memory circuit 100, in accordance with various embodiments. In the illustrated embodiment of FIG. 1, the memory circuit 100 includes a memory array 102, a row circuit 104, a column circuit 106, an input/output (I/O) circuit 108, and a control logic circuit 110. Despite not being shown in FIG. 1, the components of the memory circuit 100 may be operatively coupled to each other and to the control logic circuit 110. Although, in FIG. 1, each component is shown as a separate block for the purpose of clear illustration, in some other embodiments, some or all of the components shown in FIG. 1 may be integrated together. For example, the I/O circuit 108 may be embedded (or integrated) in the memory array 102.

The memory array 102 is a hardware component that stores data. In one aspect, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows/columns may include one or more conductive structures. In some embodiments, each memory cell 103 is arranged in the intersection of a corresponding row and a corresponding column and can be operated according to voltages or currents through the respective conductive structures of the column and row.

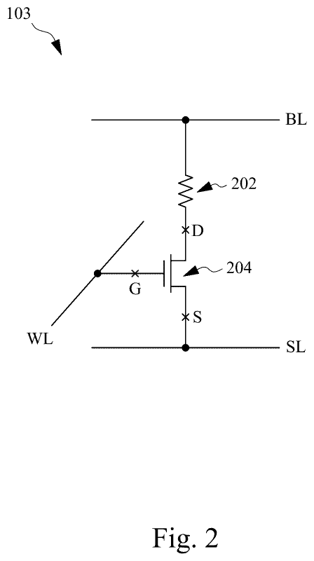

In accordance with various embodiments of the present disclosure, each memory cell 103 may be implemented as a one-time-programmable (OTP) memory cell. For example, the memory cell 103 may be an efuse cell, which includes at least a fuse resistor and an access transistor coupled in series. However, it should be understood that the memory cell 103 can be implemented as any of various other memory configurations, e.g., a static random access memory (SRAM) cell, a phase-change random access memory (PCRAM) cell, a resistive random access memory (RRAM) cell, a magnetoresistive (MRAM) random access memory cell, or the like, while remaining with the scope of the present disclosure. Detailed descriptions of the memory cell 103, configured as an efuse cell, will be discussed below with respect to FIG. 2.

The row circuit 104 is a hardware component that can receive a row address of the memory array 102 and assert a conductive structure (e.g., a word line) at that row address. The column circuit 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row circuit 104 and column circuit 106. The control logic circuit 110 is a hardware component that can control the coupled components (e.g., 102 through 108).

FIG. 2 illustrates an example configuration of the memory cell 103 (FIG. 1) configured as an efuse cell (hereinafter “efuse cell 103”), in accordance with some embodiments. The efuse cell 103 is implemented as a 1TIR configuration, for example, a fuse resistor 202 serially connected to an access transistor 204. It, however, should be understood that any of various other fuse configurations that exhibit the fuse characteristic may be used by the efuse cell 103 such as, for example, a 2-diodes-1-resistor (2DIR) configuration, a many-transistors-one-resistor (manyT1R) configuration, etc., while remaining within the scope of the present disclosure.

The fuse resistor 202 is formed of one or more metal structures. For example, the fuse resistor 202 may be one of a number of interconnect structures in one of a number of metallization layers that are disposed above the access transistor 204. The access transistor 204 can be formed over the major surface of a semiconductor substrate, which is sometimes referred to as part of front-end-of-line (FEOL) processing. Over the FEOL processing, a number of metallization layers, each of which includes a number of interconnect (e.g., metal) structures, are typically formed, which are sometimes referred to as part of back-end-of-line (BEOL) processing.

With the fuse resistor 202 (of the efuse cell 103) embodied as a metal structure, the fuse resistor 202 may present an initial resistance value (or resistivity), for example, as fabricated. To program the efuse cell 103, the access transistor 204 (if embodied as an n-type transistor) is turned on by applying a (e.g., voltage) signal, corresponding to a logic high state, through a word line (WL) to a gate terminal of the access transistor 204. Concurrently or subsequently, a sufficiently high voltage (e.g., a programming voltage) is applied on one of the terminals of the fuse resistor 202 through a bit line (BL). With the access transistor 204 turned on to provide a (e.g., program) path from the BL, through the resistor 202 and transistor 204, and to a source line (SL), such a high voltage signal can burn out a portion of the corresponding metal structure (the fuse resistor 202), thereby transitioning the fuse resistor 202 from a first state (e.g., a short circuit) to a second state (e.g., an open circuit). Accordingly, the efuse cell 103 can irreversibly transition from a first logic state (e.g., logic 0) to a second logic state (e.g., logic 1), which can be read out by applying a relatively low voltage signal on the BL and turning on the access transistor 204 to provide a (e.g., read) path.

In some embodiments of the present disclosure, a power switch of the I/O circuit 108, formed on a first semiconductor die, can constantly see (or receive) such a high programming voltage and selectively apply the programming voltage on the efuse cell 103, formed on a second semiconductor die, for a period of time. With the memory array 102 including a plural number (e.g., 4K, 16K, 64K, etc.) of the efuse cells 103, the period of time, applying on each efuse cell 103, can be accumulated. Such a total amount of the periods of time, for which the programming voltage is applied on the memory array 102, can be a factor to determine whether the access transistors 204 of the efuse cells 103 should be formed with a stacking structure. The stacking structure generally refers to coupling multiple transistors to each other in series. For example, if the total period of time is shorter than or equal to a threshold (e.g., about 0.5 seconds for a 16K memory array), the access transistors 204 may not be formed with the stacking structure; and on the other hand, if the total period of time is longer than that threshold, the access transistors 204 may be formed with the stacking structure. It can thus be appreciated that such a threshold can vary according to the size of the memory array (e.g., the number of the memory cells included therein). In some other embodiments of the present disclosure, the efuse cells 103, including their respective access transistors and resistors, may be formed on the first semiconductor die, the same as the power switch of the I/O circuit 108.

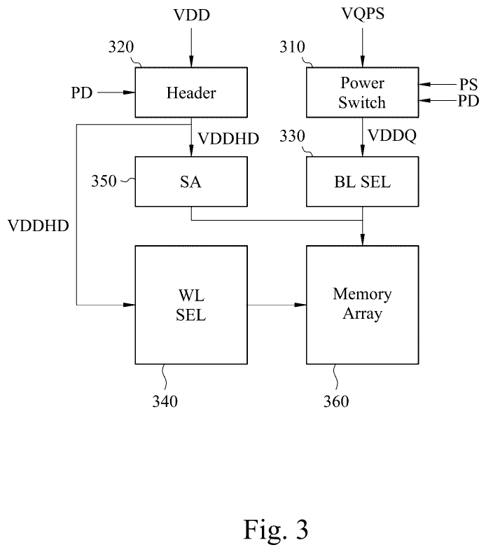

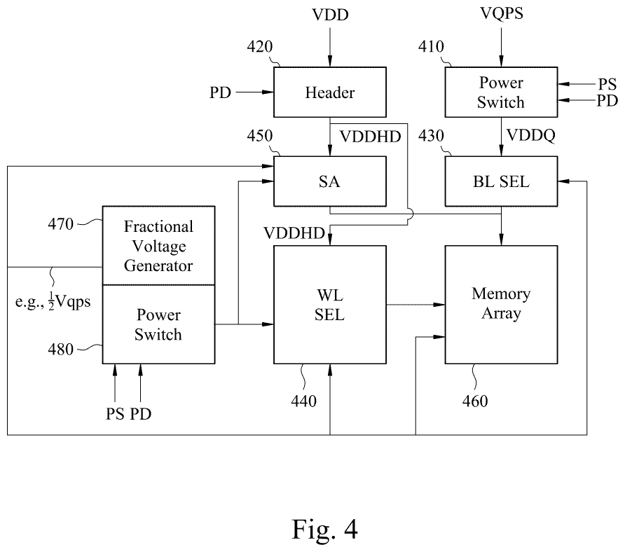

FIG. 3 and FIG. 4 respectively illustrate example block diagrams of the memory circuit 100, in accordance with some embodiments. As a brief overview, the block diagram of FIG. 3 is directed to the embodiment where the stacking structure is not implemented; and the block diagram of FIG. 4 is directed to the embodiment where the stacking structure is implemented. It should be understood that the block diagrams of FIGS. 3-4 have been simplified for illustrative purposes, and do not intend to limit the scope of the present disclosure. Thus, each of the block diagrams can include any of various other suitable components (e.g., level shifters) while remaining within the scope of the present disclosure.

Referring first to FIG. 3, the memory circuit 100 includes a power switch 310, a header circuit 320, a BL selection circuit (or sometimes referred to as BL SEL) 330, a WL selection circuit (or sometimes referred to as WL SEL) 340, a sense amplifying circuit (or sometimes referred to as SA) 350, and a memory array 360. The memory array 360 can correspond to the memory array 102 (FIG. 1); the WL selection circuit 340 can correspond to the row circuit 104 (FIG. 1); the BL selection circuit 330 can correspond to the column circuit 106 (FIG. 1); and the power switch 310, the header circuit 320, and the sense amplifying circuit 350 can correspond to the I/O circuit 108 (FIG. 1).

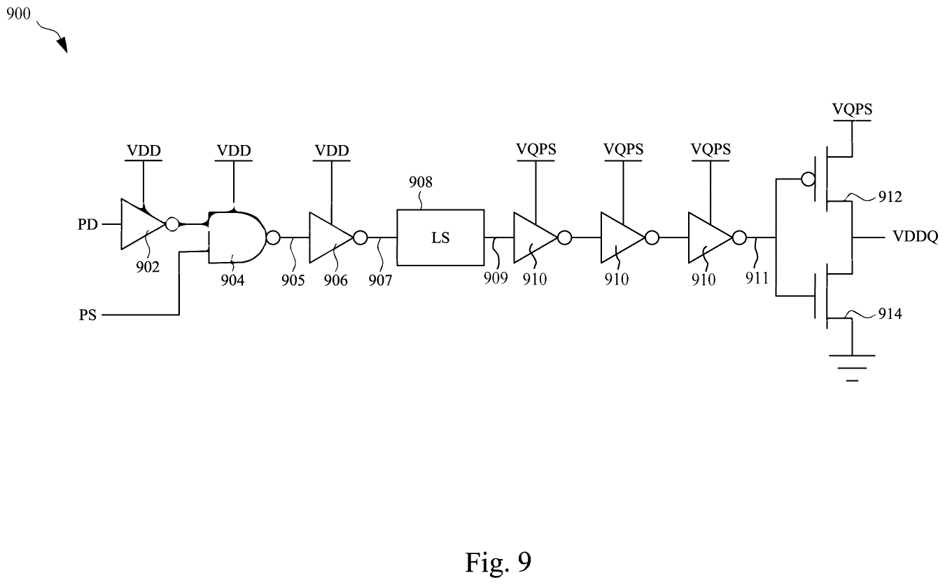

In some embodiments, the power switch 310 can receive a programming or supply voltage (VQPS), and selectively couple, based on control signals PD and PS, the VQPS to the memory array 360 through the BL selection circuit 330 as an operation voltage (VDDQ). An example circuit diagram of the power switch 310 will be discussed below in FIG. 9. Similarly, the header circuit 320 can receive a supply voltage (VDD), and selectively couple, based on the control signal PD, the VDD to the sensing amplifier circuit 350 and the WL selection circuit 340 as another operation voltage (VDDHD). As a non-limiting example, the control signal PD and control signal PS are both provided with the logic low state (i.e., PD=0 and PS=0) to read the memory array 360, or when configuring the memory array 360 in a read mode; the control signal PD and control signal PS are respectively provided with the logic low state and the logic high state (i.e., PD=0 and PS=1) to program (or write) the memory array 360, or when configuring the memory array 360 in a program mode; and the control signal PD and control signal PS are respectively provided with the logic high state and the logic low state (i.e., PD=1 and PS=0) to power down the memory array 360.

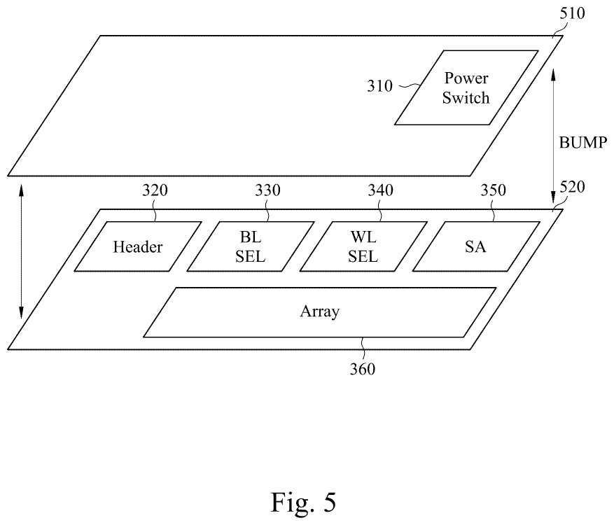

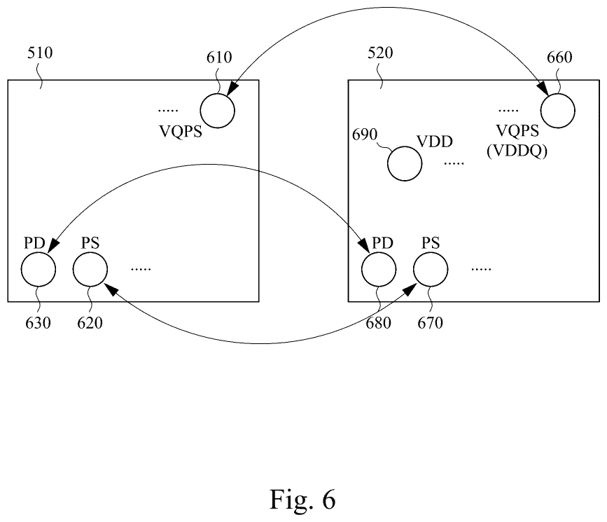

According to some embodiments, the power switch 310 may be formed on a first semiconductor die 510, while the header circuit 320, the BL selection circuit 330, the WL selection circuit 340, the sense amplifying circuit 350, and the memory array 360 may be formed on a second semiconductor die 520, as illustrated in FIG. 5. None of the power switch 310, the header circuit 320, the BL selection circuit 330, the WL selection circuit 340, the sense amplifying circuit 350, or the memory array 360 may be formed with the stacking structure. The first semiconductor die 510 and the second semiconductor die 520 can be bonded to each other through a number of bump structures, as illustrated in FIG. 6.

On the first semiconductor die 510, transistors, some of which can operatively serve as the power switch 310, can be formed with a relatively large gate feature (e.g., a longer gate length) or in a transistor structure, allowing the transistors to operate with a relatively high operation voltage (e.g., the VQPS which can be around 1.8V). On the second semiconductor die 520, transistors, some of which can operatively serve as the header circuit 320, the BL selection circuit 330, the WL selection circuit 340, the sense amplifying circuit 350, and the memory array 360, can be formed with a relatively small gate feature (e.g., a shorter gate length) or in another transistor structure, causing the transistors to operate with a relatively low operation voltage (e.g., the VDD which can be around 0.75V) or operate with the VQPS for a relatively short period of time (e.g., shorter than 0.5 seconds).

Referring then to FIG. 4, the memory circuit 100 includes a first power switch 410, a header circuit 420, a BL selection circuit 430, a WL selection circuit 440, a sense amplifying circuit 450, a memory array 460, one or more fractional voltage generators 470, and a second power switch 480. The memory array 460 can correspond to the memory array 102 (FIG. 1); the WL selection circuit 440 can correspond to the row circuit 104 (FIG. 1); the BL selection circuit 430 can correspond to the column circuit 106 (FIG. 1); and the first power switch 410, the header circuit 420, the sense amplifying circuit 450, the fractional voltage generator(s) 470, and the second power switch 480 can correspond to the I/O circuit 108 (FIG. 1).

In some embodiments, the power switch 410 can receive a programming or supply voltage (VQPS), and selectively couple, based on control signals PD and PS, the VQPS to the memory array 460 through the BL selection circuit 430 as an operation voltage (VDDQ). An example circuit diagram of the power switch 410 will be discussed below in FIG. 9. Similarly, the header circuit 420 can receive a supply voltage (VDD), and selectively couple, based on the control signal PD, the VDD to the sensing amplifier circuit 450 and the WL selection circuit 440 as another operation voltage (VDDHD). As a non-limiting example, the control signal PD and control signal PS are both provided with the logic low state (i.e., PD=0 and PS=0) to read the memory array 460, or when configuring the memory array 460 in a read mode; the control signal PD and control signal PS are respectively provided with the logic low state and the logic high state (i.e., PD=0 and PS=1) to program (or write) the memory array 460, or when configuring the memory array 460 in a program mode; and the control signal PD and control signal PS are respectively provided with the logic high state and the logic low state (i.e., PD=1 and PS=0) to power down the memory array 460.

Further, the fractional voltage generators 470 can each generate a respective fraction of the VQPS (e.g., ½×VQPS, ⅓×VQPS, ⅔×VQPS) and selectively provide the fractional voltage, through the second power switch 480, to at least the BL selection circuit 430, the WL selection circuit 440, the sense amplifying circuit 450, and the memory array 460, which may be formed with the stacking structure. A value of the fraction may be determined according to the number of transistors being stacked. For example, in a stacking structure with two transistors connected in series, the fraction is equal to ½ (e.g., ½×VQPS). In another example where a stacking structure with three transistors connected in series, the fraction is equal to ⅓ or ⅔ (e.g., ⅓×VQPS, ⅔×VQPS).

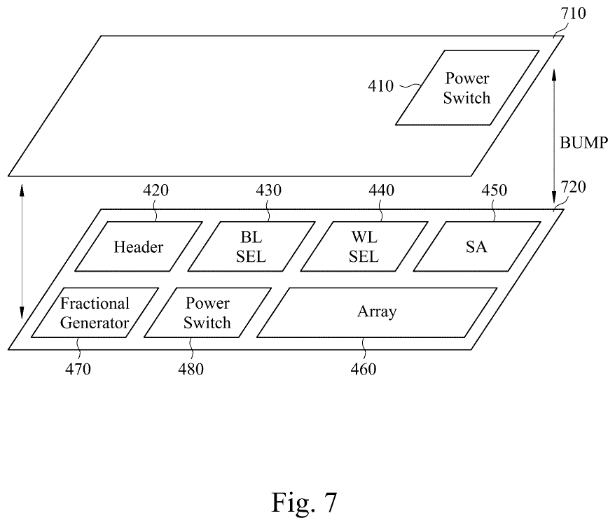

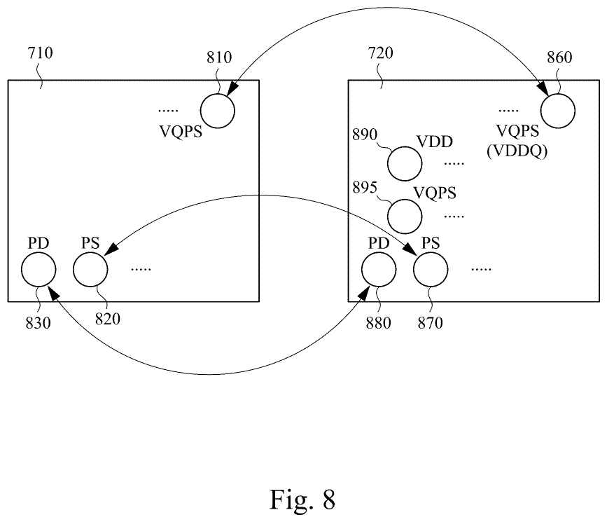

According to some embodiments, the power switch 410, without the stacking structure, may be formed on a first semiconductor die 710, while the header circuit 420, the BL selection circuit 430, the WL selection circuit 440, the sense amplifying circuit 450, the memory array 460, the fractional voltage generator 470, and the second power switch 480, with the stacking structure, may be formed on a second semiconductor die 720, as illustrated in FIG. 7. The first semiconductor die 710 and the second semiconductor die 720 can be bonded to each other through a number of bump structures, as illustrated in FIG. 8.

On the first semiconductor die 710, transistors, some of which can operatively serve as the power switch 410, can be formed with a relatively large gate feature (e.g., a longer gate length) or in a transistor structure, allowing the transistors to operate with a relatively high operation voltage (e.g., the VQPS which can be around 1.8V). On the second semiconductor die 720, transistors, some of which can operatively serve as the header circuit 420, the BL selection circuit 430, the WL selection circuit 440, the sense amplifying circuit 450, the memory array 460, the fractional voltage generator 470, and the second power switch 480, can be formed with a relatively small gate feature (e.g., a shorter gate length) or in another transistor structure, causing each of the stacking transistors to operate with a relatively low operation voltage (e.g., the VDD which can be around 0.75V) or the stacking transistors to collectively operate with the VQPS for a relatively long period of time (e.g., greater than 0.5 seconds).

Specifically, in FIG. 6, the first semiconductor die 510 and the second semiconductor die 520 are bonded to each other with a plural number of bump structures. The first semiconductor die 510 and the second semiconductor die 520, which are sometimes referred to as a top die and a bottom die, respectively, may be bonded together through suitable bonding techniques such as, for example, hybrid bonding, microbump, direct bonding, chemically activated bonding, plasma activated bonding, anodic bonding, eutectic bonding, glass frit bonding, adhesive bonding, thermo-compressive bonding, reactive bonding and/or the like. A variety of electrical connections may be provided between the first semiconductor die 510 and the second semiconductor die 520 through those bump structures.

For example, among the bump structures, the first (top) semiconductor die 510 (or its bottom surface) can house at least a number of bump structures 610, a number of bump structures 620, and a number of bump structures 630; and the second (bottom) semiconductor die 550 (or its top surface) can house at least a number of bump structures 660, a number of bump structures 670, a number of bump structures 680, and a number of bump structures 690. The bump structures 610 can be bonded to the bump structures 660, respectively, in some embodiments, allowing the power switch 310 formed on the first semiconductor die 510 to transmit the VQPS to at least the column circuit 330 formed on the second semiconductor die 520. The bump structures 620 can be bonded to the bump structures 670, respectively, in some embodiments, allowing the control signal PS to be communicated between the two semiconductor dies. The bump structures 630 can be bonded to the bump structures 680, respectively, in some embodiments, allowing the control signal PD to be communicated between the two semiconductor dies. The bump structures 690, formed on the top surface of the second semiconductor die 520, allow at least the header circuit 320 formed on the second semiconductor die 520 to receive the VDD, in some embodiments.

Specifically, in FIG. 8, the first semiconductor die 710 and the second semiconductor die 720 are bonded to each other with a plural number of bump structures. The first semiconductor die 710 and the second semiconductor die 720, which are sometimes referred to as a top die and a bottom die, respectively, may be bonded together through suitable bonding techniques such as, for example, hybrid bonding, microbump, direct bonding, chemically activated bonding, plasma activated bonding, anodic bonding, eutectic bonding, glass frit bonding, adhesive bonding, thermo-compressive bonding, reactive bonding and/or the like. A variety of electrical connections may be provided between the first semiconductor die 710 and the second semiconductor die 720 through those bump structures.

For example, among the bump structures, the first (top) semiconductor die 710 (or its bottom surface) can house at least a number of bump structures 810, a number of bump structures 820, and a number of bump structures 830; and the second (bottom) semiconductor die 750 (or its top surface) can house at least a number of bump structures 860, a number of bump structures 870, a number of bump structures 880, a number of bump structures 890, and a number of bump structures 895. The bump structures 810 can be bonded to the bump structures 860, respectively, in some embodiments, allowing the power switch 410 formed on the first semiconductor die 710 to transmit the VQPS to at least the column circuit 430 formed on the second semiconductor die 720. The bump structures 820 can be bonded to the bump structures 870, respectively, in some embodiments, allowing the control signal PS to be communicated between the two semiconductor dies. The bump structures 830 can be bonded to the bump structures 880, respectively, in some embodiments, allowing the control signal PD to be communicated between the two semiconductor dies. The bump structures 890, formed on the top surface of the second semiconductor die 720, allows at least the header circuit 420 formed on the second semiconductor die 720 to receive the VDD, in some embodiments. The bump structures 895, formed on the top surface of the second semiconductor die 720, allows at least the one or more fractional voltage generators 470 formed on the second semiconductor die 720 to receive the VQPS, in some embodiments.

FIG. 9 illustrates an example circuit diagram of a power switch 900 (e.g., the power switch 310 of FIG. 3, the power switch 410 of FIG. 4), in accordance with some embodiments. The power switch 900 can provide an operation voltage (e.g., VDDQ) configured for programming a number of memory cells (e.g., efuse cells 103). The power switch 900 can provide the operation voltage VDDQ shifted from a first voltage domain (e.g., from 0V to VDD) to a second voltage domain (e.g., from OV to VQPS). In the example of FIG. 9, the power switch 900 is formed without a stacking structure, or formed on a semiconductor die allowing multiple gate lengths, a relatively long gate length, and/or the formation of I/O transistors. However, it should be appreciated that the foregoing power switch (e.g., 310, 410) is not limited to being formed without a stacking structure.

As shown, the power switch 900 includes inverter 902, NAND gate 904, inverter 906, level shifter 908, an (odd) number of inverters 910, pull-up transistor 912, and pull-down transistor 914. In some embodiments, the inverter 902, NAND gate 904, and inverter 906 can operate in the first voltage domain (e.g., between OV and the VDD which may be around 0.75V); and the inverters 910, pull-up transistor 912, and pull-down transistor 914 can operate in the second voltage domain (e.g., between OV and the VQPS which may be around 1.8V).

The inverter 902 can receive the above-mentioned control signal PD (e.g., through a first control pin), and provide the inverted control signal PD to one of the inputs of the inverter 902. The NAND gate 904 can also receive the control signal PS (e.g., through a second control pin), and perform a NAND operation on the control signal PD inverted and the control signal PS to provide signal 905 (psvq). The control signals PD and PS, with respective logic states, can be provided in the first voltage domain. For example, when configured at the logic high state, the control signal PD/PS is provided at 0.75V; and when configured at the logic low state, the control signal PD/PS is provided at OV. The inverter 906 can invert the signal 905 as signal 907 (psvqb). The level shifter 908 can receive the signal 905 and 907 as a differential pair of input signals, and shift the signal 905/907 to provide signal 909 (pqb).

For example, when the signal 907 (psvqb) is received by the level shifter 908 with the logic high state, the level shifter 908 can provide the signal 909 (pqb) with the logic high state, where the signal 907 and signal 909 are around 0.75V and 1.8V, respectively. The inverters 910 can provide signal 911 by inverting the signal 909. The pull-up transistor 912 can have its gate terminal receiving the signal 911, and the pull-down transistor 914 can have its gate terminal receiving the signal 911. Further, the pull-up transistor 912 (which may be implemented as a p-type transistor) can have its source terminal connected to the second supply voltage VQPS, and the pull-down transistor 914 (which may be implemented as an n-type transistor) can have its source terminal connected to the ground voltage, where respective drain terminals of the transistors 912 and 914 are connected to each other at an output node to provide the operation voltage VDDQ.

When in the read mode, the control signal PD and control signal PS are both provided with the logic low state (i.e., PD=0 and PS=0). As such, the signal 907, input to the level shifter 908, is at the logic low state, the signal 909, output from the level shifter 908, is at the logic low state, and the signal 911, output from the odd number of inverters 910, is at the logic high state, which causes the transistors 912 and 914, operatively serving as an inverter, to output the operation voltage VDDQ equal to about OV through turning on the transistor 914. When in the program mode, the control signal PD and control signal PS are respectively provided with the logic low state and the logic high state (i.e., PD=0 and PS=1). As such, the signal 907, input to the level shifter 908, is at the logic high state, and the signal 909, output from the level shifter 908, is at the logic high state, and the signal 911, output from the odd number of inverters 910, is at the logic low state, which causes the transistors 912 and 914, operatively serving as an inverter, to output the operation voltage VDDQ equal to about 1.8V (VQPS) through turning on the transistor 912.

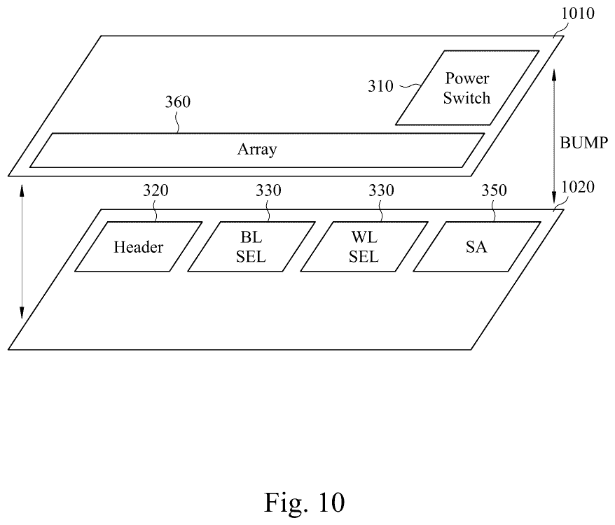

Relative to the embodiments shown in FIGS. 5-8, FIG. 10 illustrates another embodiment implementing the memory circuit 100 (e.g., based on the block diagram of FIG. 3). Accordingly, some of the reference numerals of FIG. 3 may be again used in the following discussion. As shown, the power switch 310 and the memory array 360 may be formed on a first semiconductor die 1010, while the header circuit 320, the BL selection circuit 330, the WL selection circuit 340, and the sense amplifying circuit 350 may be formed on a second semiconductor die 1020. The first semiconductor die 1010 and the second semiconductor die 1020 can be bonded to each other through a number of bump structures.

Other than the implementations of FIGS. 3, 5, or 10, the memory circuit 100 can be implemented in an alternative or additional arrangement. For example, a first semiconductor die may house only one or more memory arrays (e.g., 360), while other circuit components (e.g., 310, 320, 330, 340, and 350) may be formed in a second semiconductor die, and the first semiconductor die and the second semiconductor die are bonded to each other through a number of bump structures.

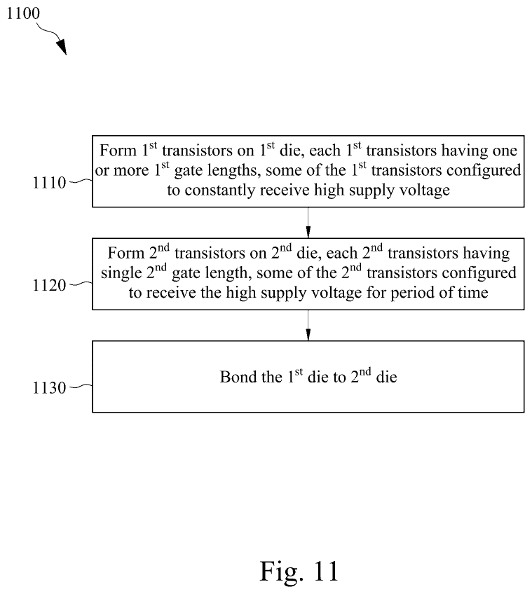

FIG. 11 illustrates a flowchart of a method 1100 to form a memory circuit including different dies operatively coupled to each other through a number of bump structures, according to one or more embodiments of the present disclosure. For example, at least some of the operations (or steps) of the method 1100 can be used to form a memory circuit discussed above. It is noted that the method 1100 is merely an example, and is not intended to limit the present disclosure. Accordingly, it should be understood that additional operations may be provided before, during, and/or after the method 1100 of FIG. 11, and that some other operations may only be briefly described herein.

The method 1100 can start with operation 1110 of forming a plurality of first transistors on a first semiconductor die, each of the plurality of first transistors having a first gate length. In some embodiments, a subset of the plurality of first transistors are configured to constantly receive a relatively high supply voltage. The first semiconductor die may be a first semiconductor substrate, such as a bulk silicon semiconductor, a semiconductor-on-insulator (SOI) substrate, or the like, which may be doped (e.g., with a p-type or an n-type dopant) or undoped.

On the first semiconductor substrate (die), the first transistors can be formed along a major surface of the first semiconductor substrate. The first transistors may be formed with one or more first gate lengths. The first transistors may be formed with one or more of the FinFET structure or planar transistor structure. In some embodiments, some of the first transistors can operatively serve as the power switch (e.g., 310, 410) of a memory circuit that may constantly see (or receive) a relatively high supply voltage, e.g., the VQPS which is around 1.8V or higher. As mentioned above (e.g., FIG. 9), the power switch can be controlled by one or more control signals (e.g., PS, PD) to selectively couple the high supply voltage to other components of the memory circuit, which may be formed on another semiconductor substrate.

The method 1100 can proceed to operation 1120 of forming a plurality of second transistors on a second semiconductor die, each of the plurality of second transistors having a second gate length shorter than the first gate length. In some embodiments, a subset of the plurality of second transistors are configured to receive the supply voltage from the subset of the first transistors for a period of time. The second semiconductor die may be a second semiconductor substrate, such as a bulk silicon semiconductor, a semiconductor-on-insulator (SOI) substrate, or the like, which may be doped (e.g., with a p-type or an n-type dopant) or undoped.

On the second semiconductor substrate (die), the second transistors can be formed along a major surface of the second semiconductor substrate. The second transistors may be configured to be formed with a single second gate length that is substantially shorter than any of the one or more first gate lengths. The second transistors may be configured to be formed with one or more of the GAA transistor structure or complementary field-effect-transistor structure. For example, the second transistors are laid out with a unified, shorter gate length, while the first transistors are laid out with multiple, longer gate lengths. However, it would be appreciated that, upon fabrication, the second transistors may still present various gate lengths, one or more of which are longer than a gate length of the first transistors, for example, due to process variation. In some embodiments, some of the second transistors can operatively serve as the header circuit (e.g., 320, 420), the BL selection circuit (e.g., 330, 430), the WL selection circuit (e.g., 340, 440), the sense amplifying circuit (e.g., 350, 450), the memory array (e.g., 360, 460), the fractional voltage generator (e.g., 470), or the fractional power switch (e.g., 480) of the memory circuit. Each of these circuit components formed on the second semiconductor die may have its second transistors see (or receive) a relatively low supply voltage, e.g., the VDD which is around 0.75V, or receive the high supply voltage (VQPS) for a period of time. Further, in some embodiments, if the period of time is estimated to be equal to or shorter than a threshold, the second transistors may be formed without the stacking structure. The threshold can be determined according to a size of the memory array. On the other hand, if the period of time is estimated to be longer than the threshold, the second transistors may be formed with the stacking structure.

The method 1100 can proceed to operation 1130 of bonding the first semiconductor die to the second semiconductor die with a plurality of bump structures. Such bump structures can each include a solder ball, a metal pillar, a controlled collapse chip connection (C4) bump, a micro bump, an electroless nickel-electroless palladium-immersion gold technique (ENEPIG) formed bump, a through silicon/substrate via, a combination thereof (e.g., a metal pillar having a solder ball attached thereof), or the like. As a result, the first transistors formed on the first semiconductor die can communicate with the second transistors formed on the second semiconductor die.

In one embodiment, the first semiconductor die and the second semiconductor die may be bonded to each other, with a face-to-face (F2F) orientation. For example, over FEOL processing of the first semiconductor die (where the first transistors are formed), BEOL processing (which includes a number of first metallization layers) can be formed. Similarly, over FEOL processing of the second semiconductor die (where the second transistors are formed), BEOL processing (which includes a number of second metallization layers) can be formed. A number of micro bumps can be formed between a topmost one of the first metallization layers and a topmost one of the second metallization layers.

In another embodiment, the first semiconductor die and the second semiconductor die may be bonded to each other, with a face-to-back (F2B) orientation. For example, over FEOL processing of the first semiconductor die (where the first transistors are formed), BEOL processing (which includes a number of first metallization layers) can be formed. Similarly, over FEOL processing of the second semiconductor die (where the second transistors are formed), BEOL processing (which includes a number of second metallization layers) can be formed. A number of metal pillars (sometimes referred to as through silicon vias) can be formed to extend through a substrate of the second semiconductor die, so as to connect at least a topmost one of the first metallization layers.

In one aspect of the present disclosure, a semiconductor device is disclosed. The semiconductor device includes a first semiconductor die including a plurality of first transistors, wherein the plurality of first transistors each have a first gate feature; and a second semiconductor die coupled to the first semiconductor die through a plurality of bump structures, and including a plurality of second transistors, wherein the plurality of second transistors each have a second gate feature smaller than the first gate feature. At least a subset of the plurality of first transistors, operatively serve as one or more power switches, are configured to receive a first supply voltage and electrically couple the first supply voltage to a subset of the plurality of second transistors for a period of time.

In another aspect of the present disclosure, a semiconductor device is disclosed. The semiconductor device includes a first semiconductor die including a plurality of first transistors, wherein the plurality of first transistors are each constructed with a first transistor structure; and a second semiconductor die coupled to the first semiconductor die, and including a plurality of second transistors, wherein the plurality of second transistors are each constructed with a second transistor structure. At least a subset of the plurality of first transistors are configured to receive a first supply voltage and electrically couple the first supply voltage to a subset of the plurality of second transistors for a period of time that satisfies a threshold.

In yet another aspect of the present disclosure, a method for fabricating semiconductor devices is disclosed. The method includes forming a plurality of first transistors on a first semiconductor die, each of the plurality of first transistors having a first gate feature, wherein a subset of the plurality of first transistors are configured to receive a supply voltage. The method includes forming a plurality of second transistors on a second semiconductor die, each of the plurality of second transistors having a second gate feature smaller than the first gate feature, wherein a subset of the plurality of second transistors are configured to receive the supply voltage from the subset of the first transistors for a period of time. The method includes bonding the first semiconductor die to the second semiconductor die with a plurality of bump structures.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first semiconductor die including a plurality of first transistors, wherein the plurality of first transistors each have a first gate feature; and
a second semiconductor die coupled to the first semiconductor die through a plurality of bump structures, and including a plurality of second transistors, wherein the plurality of second transistors each have a second gate feature smaller than the first gate feature;
wherein at least a subset of the plurality of first transistors, operatively serve as one or more power switches, are configured to receive a first supply voltage and electrically couple the first supply voltage to a subset of the plurality of second transistors for a period of time.

2. The semiconductor device of claim 1, wherein the period of time is configured to be equal to or shorter than a threshold.

3. The semiconductor device of claim 2, wherein the subset of the second transistors are each configured to operatively serve, in part, as a sense amplifier, a level shifter, or a memory cell, and wherein none of the subset of the second transistors has a stacking structure.

4. The semiconductor device of claim 1, wherein the period of time is configured to be longer than a threshold.

5. The semiconductor device of claim 4, wherein the subset of the second transistors are each configured to operatively serve, in part, as a sense amplifier, a level shifter, or a memory cell, and wherein each of the subset of the second transistors has a stacking structure.

6. The semiconductor device of claim 1, wherein the subset of the first transistors are each constructed with a FinFET structure or a planar transistor structure, while the subset of the second transistors are each constructed with a Gate-All-Around (GAA) transistor structure.

7. The semiconductor device of claim 1, wherein at least one of the bump structures is configured to receive a control signal to control the period of time.

8. The semiconductor device of claim 1, wherein at least one of the bump structures is configured to receive the first supply voltage.

9. The semiconductor device of claim 1, wherein at least one of the bump structures is configured to receive a second supply voltage powering one or more of the subset of the second transistors, the second supply voltage being lower than the first supply voltage.

10. The semiconductor device of claim 1, wherein some of the subset of the second transistors operatively form a memory array including a plurality of memory cells, each of the plurality of memory cells including a resistor serially coupled to one or more of the second transistors.

11. The semiconductor device of claim 1, wherein some of the subset of the first transistors operatively form a memory array including a plurality of memory cells, each of the plurality of memory cells including a resistor serially coupled to a singular number of the first transistors.

12. A semiconductor device, comprising:
a first semiconductor die including a plurality of first transistors, wherein the plurality of first transistors are each constructed with a first transistor structure; and
a second semiconductor die coupled to the first semiconductor die, and including a plurality of second transistors, wherein the plurality of second transistors are each constructed with a second transistor structure;
wherein at least a subset of the plurality of first transistors are configured to receive a first supply voltage and electrically couple the first supply voltage to a subset of the plurality of second transistors for a period of time that satisfies a threshold.

13. The semiconductor device of claim 12, wherein the period of time is configured to be equal to or shorter than the threshold.

14. The semiconductor device of claim 13, wherein the subset of the first transistors are configured to operatively serve as one or more power switches, while the subset of the second transistors each configured to operatively serve, in part, as a sense amplifier, a level shifter, or a memory cell, and wherein none of the subset of the second transistors has a stacking structure.

15. The semiconductor device of claim 12, wherein the period of time is configured to be longer than the threshold.

16. The semiconductor device of claim 15, wherein the subset of the first transistors are configured to operatively serve as one or more power switches, while the subset of the second transistors each configured to operatively serve, in part, as a sense amplifier, a level shifter, or a memory cell, and wherein each of the subset of the second transistors has a stacking structure.

17. The semiconductor device of claim 12, wherein the first transistor structure has one or more first gate lengths, while the second transistor structure has a single second gate length.

18. The semiconductor device of claim 17, wherein the second gate length is shorter than any of the one or more first gate lengths.

19. A method for forming semiconductor devices, comprising:
forming a plurality of first transistors on a first semiconductor die, each of the plurality of first transistors having a first gate feature, wherein a subset of the plurality of first transistors are configured to receive a supply voltage;
forming a plurality of second transistors on a second semiconductor die, each of the plurality of second transistors having a second gate feature smaller than the first gate feature, wherein a subset of the plurality of second transistors are configured to receive the supply voltage from the subset of the first transistors for a period of time; and
bonding the first semiconductor die to the second semiconductor die with a plurality of bump structures.

20. The method of claim 19, wherein the subset of the first transistors are configured to operatively serve as one or more power switches, while the subset of the second transistors each configured to operatively serve, in part, as a sense amplifier, a level shifter, or a memory cell.
